(19) United States
(12) Patent Application Publication
(10) Pub. No.: US 2005/0012498 A1
(43) Pub. Date: Jan. 20, 2005

(54) System and method for testing semiconductor devices

(76) Inventors: Soo-Chan Lee, Cheonan-city (KR); Young-Kyun Sun, Cheonan-city (KR); Hyun-Ho Kim, Cheonan-city (KR); Byeong-Chun Lee, Seoul (KR); Jun-Ho Lee, Yongin-city (KR); Jong-Cheol Lee, Cheonan-city (KR); Je-Hyoung Ryu, Suwon-city (KR); Tae-Gyu Kim, Gyeonggi-do (KR); Soon-Kyu Yim, Seongnam-city (KR)

Correspondence Address: ALEXANDER FRANKLIN MAYER, 12910 BROOKPARK RD., OAKLAND, CA, 94619, US

(21) Appl. No.: 10/791,629

(22) Filed: Mar. 3, 2004

(30) Foreign Application Priority Data
Jul. 14, 2003 (KR) 2003-48083

(51) Int. Cl. G01R 31/02

(52) U.S. Cl. 324/158.1

(57) ABSTRACT

A semiconductor device test apparatus includes a main body and a stacker for stacking devices before and after a test. The stacker includes at least one user tray feeder predesignated with a function for stacking un-tested devices and at least one user tray sender predesignated with a function for stacking tested devices, the user tray functions being interchangeable during stacker operation.

This U.S. nonprovisional patent application claims priority under 35 U.S.C. § 119 of Korean Patent Application 2003-48083 filed on Jul. 14, 2003, the entire contents of which are hereby incorporated by reference.

### BACKGROUND OF THE INVENTION

A test apparatus may be classified for testing semiconductor devices in high temperature, room temperature, or lower temperature conditions.

The test apparatus may implement a test by submitting a number of semiconductor devices for testing and maintaining contact with the semiconductor devices via a test head. The test apparatus further classifies and loads the devices in accordance with the result of the test. The test apparatus then sends the devices to a test area to test 32 to 64 devices simultaneously. The devices may then be tested in a special temperature environment, such as a low or a high temperature environment.

An example of such a semiconductor device test apparatus was disclosed in a Korea Laid Open Patent Publication (Application No. 10-1999-7001710 (WO99/01776) entitled “Semiconductor Device Test Apparatus and Test Tray Used In The Apparatus”). The above patent publication provides an integrated circuit (IC) tester capable of reducing consumption time until completion of all the IC tests. The inner lengths of a constant temperature chamber and an outlet chamber (the length of Y-axis direction) for testing are made to roughly correspond to the width of rectangular test tray (the length of end edge). Two transporting paths are installed to be roughly parallel to each other, which extend from a soak chamber in the constant temperature chamber to an outlet chamber by way of a tester in the constant temperature chamber. Alternatively, two test trays are installed in a direction crossing transporting paths of the test trays so as to carry objects simultaneously along wide width paths. With the above structure, it is possible to simultaneously carry two test trays along the two transporting paths or the wide width transporting paths.

An example of a test tray is disclosed in a Slocom patent (U.S. Pat. No. 6,097,201). The Slocom test tray is characterized in that a stack of a test board is provided in a test chamber and a tray is inserted into the stacked test board to perform a test. The tray is put in contact with a device on the tray and a contact area on the test board by pushing the tray toward the board.

In the processes performed by the semiconductor device test apparatuses described above, the temperature of the device is controlled to help prevent the reliability of the test from deteriorating due to heat generated in the device.

A Japanese Laid Open Patent Publication (Patent Open No.2001-13201 entitled “Method And Apparatus For Testing IC Device”) discloses a device for controlling the temperature of the device. The apparatus includes a chamber in which a transporting tray having a number of IC devices is carried and a test of the IC device is performed, a pre-heater for heating or cooling the IC device to a predetermined temperature, a contact pusher support used when measuring an electrical characteristic of the IC device, and a plurality of devices under test (DUTs). The contact pusher includes an IC contact-type heat source for heating or cooling each IC device in its lower part, and IC individual temperature sensors for measuring the temperature of each IC device.

A disadvantage of the semiconductor device test apparatuses, as discussed above, is that each chamber (soak chamber, test chamber and desoak chamber) is part of a uni-body construction of the test apparatus. This makes it troublesome to check the test apparatus in cases that the equipment is out of order or malfunctions.

Another disadvantage of the semiconductor device test apparatus in a conventional semiconductor device test apparatus, is that a user tray feeder for supplying a user tray and a user tray sender for sending the user tray are used at prescribed positions. As a result, user tray feeders needed before the devices are tested are committed and unavailable and user tray senders needed after the devices have been tested are also committed and unavaible so that the number of the user tray feeders and senders increases over time based on test production.

A further disadvantage is that an insert constituting the test tray has a construction that the insert receives the devices one by one so that each test tray accommodates 32 to 64 devices. Accordingly, the number of devices tested for a particular time period is limited so that the total yield decreases.

Another disadvantage with the semiconductor device test apparatuses discussed above is that controlling of the device temperature depends only on convection air flowing around the devices. Accordingly, the temperature control effect is less effective when the devices are highly heated. Further, the air flow is inhibited by an insert, a pusher or a socket which supports the devices, which helps prevent air from circulating freely.

A further disadvantage of the semiconductor device test apparatuses discussed above is that each robotic carrying device used in the testing process always moves at a high speed regardless of an actual test time of the devices. As a result, the robotic carrying device becomes fatigued when operating.

### SUMMARY OF THE INVENTION

In an example embodiment of the invention, a semiconductor device test apparatus includes a main body; a soak chamber; a test chamber; and a desoak chamber; wherein the soak chamber, the test chamber, and the desoak chamber can be separated from the main body.

In another example embodiment of the invention, a semiconductor device test apparatus includes a main body; and a stacker for stacking devices before and after a test, the stacker including user trays for stacking the devices, the user trays being interchangeable such that the user trays may be used to stack the devices prior to the test and to stack the devices after the test.

In a further example embodiment of the invention, a semiconductor device test apparatus including a main body; a stacker for stacking devices before and after a test, the stacker including at least one user tray feeder predesignated with a function for stacking un-tested devices and at least one user tray sender predesignated with a function for stacking tested devices, the user tray functions being interchangeable during stacker operation.

In still another further example embodiment of the inveniton, a semiconductor device test apparatus includes a main body; and a stacker arranged in the main body, the stacker having a user tray feeder which loads a plurality of user trays having a desired quantity of devices to be tested and a user tray sender which loads the plurality of user trays having the devices sorted by their grades in accordance with the test result, the user tray feeder and the user tray sender being interchanged in their uses in accordance with the process of the test.

In another example embodiment of the invention, a semiconductor device test apparatus includes a test chamber for providing desired test space; at least one test head installed on one side of the test chamber; and a socket assembly having a socket block and a plurality of socket guides, the socket block being arranged on the test head at a desired interval in a matrix form and having a plurality of sockets contacted with a plurality of devices, the socket guide covering an upper part of the socket block and having a plurality of socket guides provided with a plurality of windows to pass through a contact pin of the socket. The a semiconductor device test apparatus also including a test tray for loading a plurality of inserts and for arranging the inserts in a matrix form corresponding to the arrangement form of the socket, the inserts having a plurality of device receivers to receive devices corresponding to the plurality of sockets; and a lead pusher assembly having a match plate, a plurality of pressure plates and a plurality of pushers, the match plate being arranged in parallel with the test head and being connected to a driving unit, the pressure plates being arranged in the match plate through a contact block in a matrix form corresponding to the insert arrangement form, the pushers being arranged in a side of the pressure plate and pressing a lead of the device.

In another example embodiment of the invention, a semiconductor device test apparatus includes a test chamber; at least one test head installed in one side of the test chamber; a plurality of sockets installed on the test head; a test tray having an insert receiving a plurality of devices to be contacted with the socket; and a lead pusher assembly including. The lead pusher assembly including a pusher for pressing a lead of the device, a pressure plate on the pusher, a contact block installed on the pressure plate, and a match plate in contact with the upper edge of the contact block and having a plurality of through holes to open the upper edge of the contact block. The semiconductor device test appratus further includes a conductor that penetrates an inner part of the pusher, the conductor making its bottom contacted with the upper surface of the device, the conductor having an upper part that passes through the pressure plate; and a heat sink including a central and inner part that are connected to the upper part of the conductor, the heat sink radiates the heat conducted from the conductor.

In still another example embodiment of the invention, a semiconductor device test apparatus includes a perforated heat sink including a conductor extended from the perforated heat sink, the conductor being in direct contact with a device during a testing cycle to dissipate heat from the device during the testing cycle.

In further example embodiment of the invention, a semiconductor device test apparatus including a loading robot for picking up devices to be tested which are in a stand-by status in a user tray feeder and mounting the devices on a test tray, the test tray being on a device loading stage; a sorting robot for picking up the device discharged to the device unloader and for carrying the device discharged to a plurality of sorter tables in accordance with the test result, and an unloading robot for picking up the device carried to the sorter table and for carrying the device to the user tray sender. The operating speeds of the loading robot, the sorting robot, and the unloading robot is determined based on the speed of testing the device.

In another example embodiment of the invention, a method for constructing a semiconductor device test appartus includes attaching, during manufacture, a soak chamber, a test chamber, and a desoak chamber to a main body so that the soak chamber, the test chamber, and the desoak chamber, may be later separated.

In still another example embodiment of the invention, a method for stacking devices in a semiconductor test apparatus includes predesignating at least one user tray feeder for stacking un-tested devices; predesignating at least one user tray sender for stacking tested devices; designating at least one user tray feeder for stacking tested devices based on the test; and stacking at least one tested device on the at least one user tray feeder.

In another example embodiment of the inveniton, a method for testing a device using a semiconductor device test apparatus includes providing a test chamber with a desired test space; installing at least one test head on one side of the test chamber; arranging a socket block and a plurality of socket guides to form a socket assembly, the socket block being positioned on the test head at a desired interval in a matrix form and having a plurality of sockets contacted with a plurality of devices, the socket guide covering an upper part of the socket block and having a plurality of socket guides provided with a plurality of windows to pass through a contact pin of the socket; loading a plurality of inserts using a test tray; arranging the inserts in a matrix to correspond to the arrangement of the socket, the inserts having a plurality of device receivers to receive devices corresponding to the plurality of sockets; and assembling a lead pusher assembly to include a match plate, a plurality of pressure plates and a plurality of pushers, the match plate being arranged in parallel with the test head and being connected to a driving unit, the pressure plates being arranged in the match plate through a contact block in a matrix corresponding to the insert arrangement, the pushers being arranged in a side of the pressure plate and pressing a lead of the device.

In a further example embodiment of the invention, a method for testing a semiconductor device includes contacting a conductor, that extends away from a perforated heat sink, with the device during the testing cycle to dissipate heat from the device; and flowing air through the perforations of the heat sink to make contact with the heat sink, the conductor, and the device to help control the temperature of the device during the testing cycle.

In another example embodiment of the invention, a method for controling a robot speed of a semiconductor device test apparatus, includes sending control signals to at least one robot to carry a device for a test; detecting a time for the test; calculating a desired speed value of the robot corresponding to the test time detected; and informing the corresponding robot of the calculated speed value to control the speed of the robot.

### BRIEF DESCRIPTION OF THE DRAWINGS

The above will be more clearly understood from the following detailed description taken in conjunction with the accompanying drawings, in which:

FIG. 1 is an example perspective view showing a construction of a semiconductor device test apparatus in accordance with an example embodiment of the invention;

FIG. 2 is an example plane view of FIG. 1 in accordance with an example embodiment of the invention;

FIGS. 3a-e are example illustrations for explaining how user trays are used in accordance with an example embodiment of the invention;

FIG. 4 is an example perspective view showing a chamber separation construction of a semiconductor device test apparatus in accordance with an example embodiment of the invention;

FIG. 5 is an example plane view of parts shown in FIG. 4 in accordance with an example embodiment of the invention;

FIG. 6 is an example perspective view showing an upper part of a test chamber in accordance with an example embodiment of the invention;

FIG. 7 is an example sectional view of the semiconductor device test apparatus of FIG. 4 in accordance with an example embodiment of the invention;

FIG. 8 is an example exploded view of part of the semiconductor device test apparatus shown in FIG. 6 in accordance with an example embodiment of the invention;

FIG. 9 is an example sectional view of a portion of the semiconductor device test apparatus of FIG. 8 in accordance with an example embodiment of the invention;

FIG. 10 is an example plane view showing a test tray in accordance with an example embodiment of the invention;

FIG. 11 is an example sectional view of part of the test tray shown in FIG. 10 in accordance with an example embodiment of the invention;

FIG. 12 is an example perspective view showing parts of FIG. 9 in accordance with an example embodiment of the invention;

FIGS. 13 to 15 are example magnified views of parts of FIG. 12 in accordance with an example embodiment of the invention;

FIG. 16 is an example separated perspective view of parts shown FIG. 9, which is viewed from the opposite direction of FIG. 12 in accordance with an example embodiment of the invention;

FIGS. 17 to 19 are example magnified views of parts of FIG. 16 in accordance with an example embodiment of the invention; and

FIG. 20 is an example flow chart showing how to control a robot speed of a semiconductor device test apparatus in accordance with an example embodiment of the invention.

### DETAILED DESCRIPTION OF THE EXAMPLE EMBODIMENTS

Example embodiments of the present invention are now described in detail with reference to the drawings.

### Semiconductor Device Test Apparatus

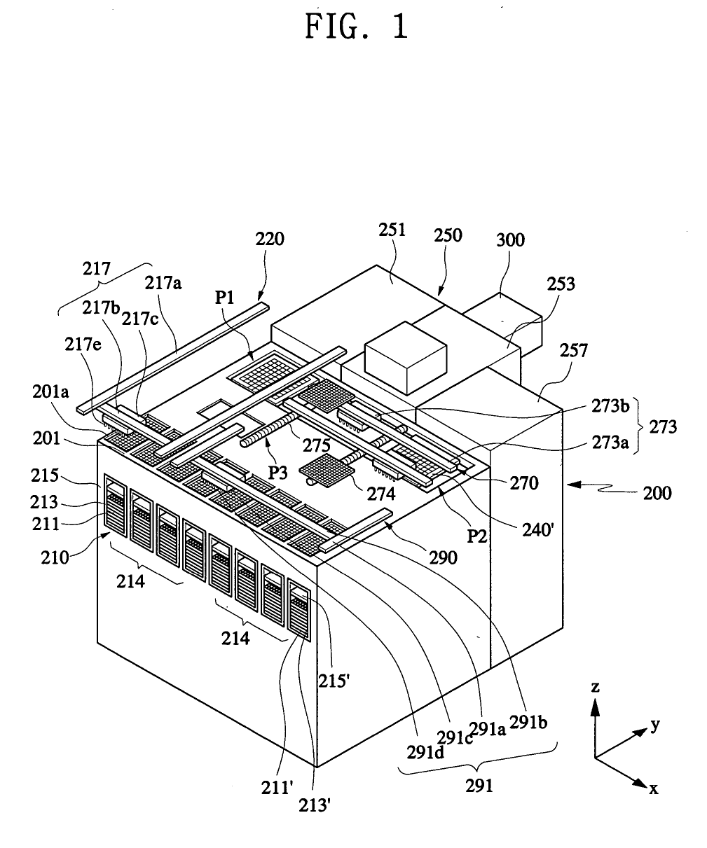

An example embodiment of a semiconductor device test apparatus is now described with reference to FIGS. 1 to 5.

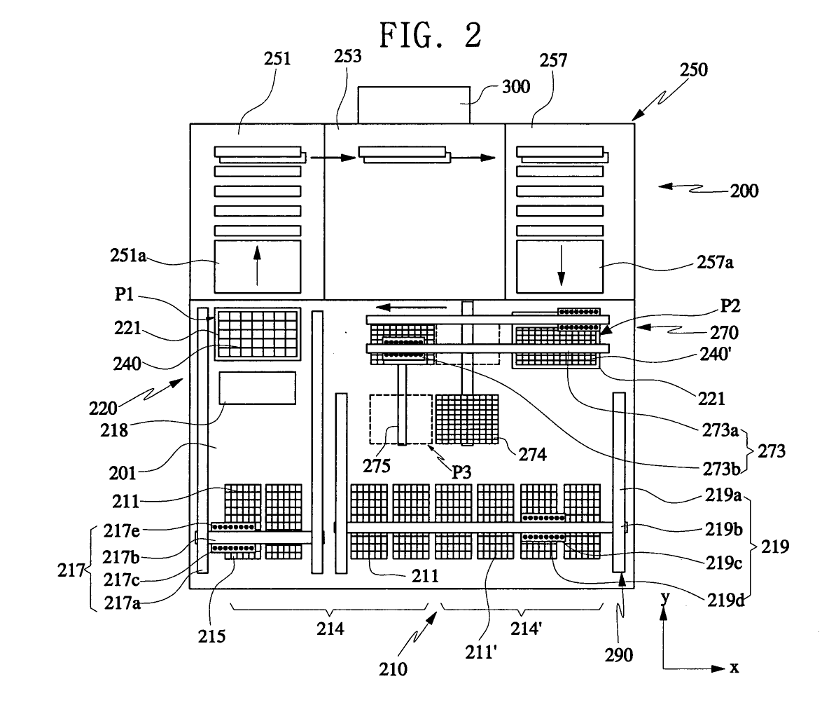

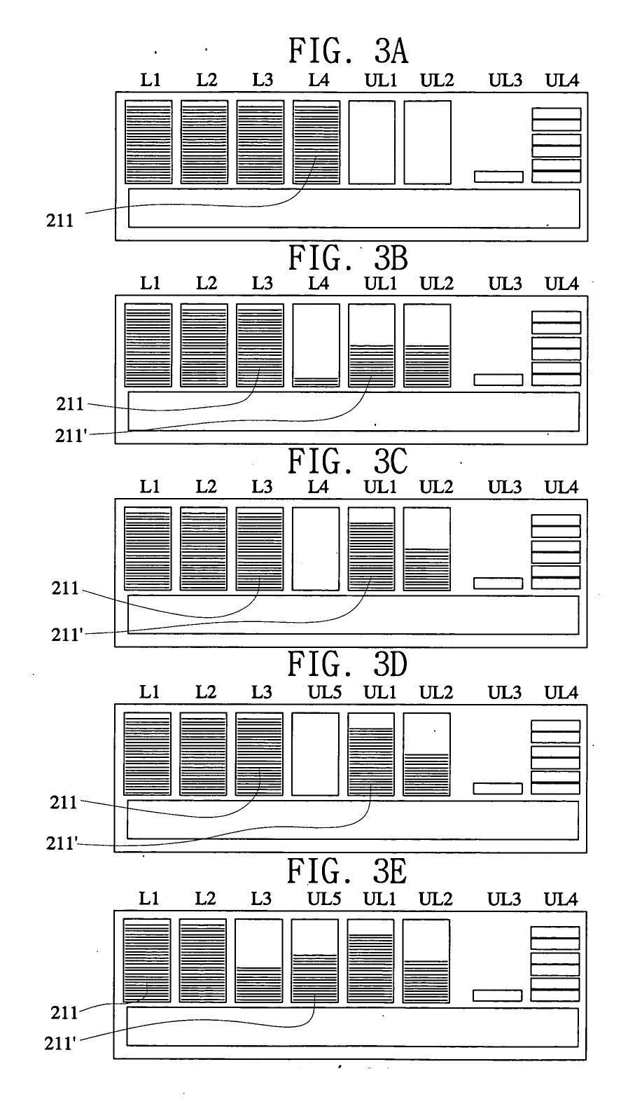

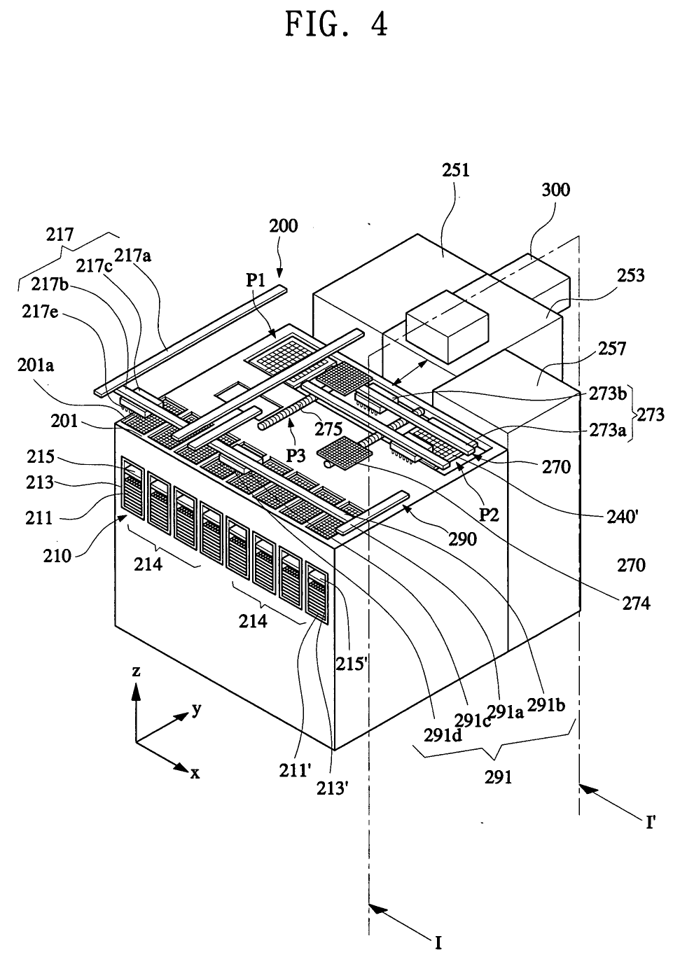

FIG. 1 is an example perspective view showing a construction of a semiconductor device test apparatus in accordance with an example embodiment of the invention. FIG. 2 is an example plane view of FIG. 1 in accordance with an example embodiment of the invention. FIGS. 3a-3 are an example illustration for explaining how user trays are used in accordance with an example embodiment of the invention. FIG. 4 is an example perspective view showing a chamber separation construction of a semiconductor device test apparatus in accordance with an example embodiment of the invention.

Referring to FIGS. 1 and 2, the semiconductor device test apparatus includes a test handler 200 and a test head 300.

The test handler 200 carries devices to be tested to a socket installed in the test head 300, sorts the devices tested in accordance with a result of the test, and performs an operation to load the sorted devices on a tray. The test handler 200 includes a stacker 210, a device loader 220, a chamber 250, a sorter 270, and a device unloader 290.

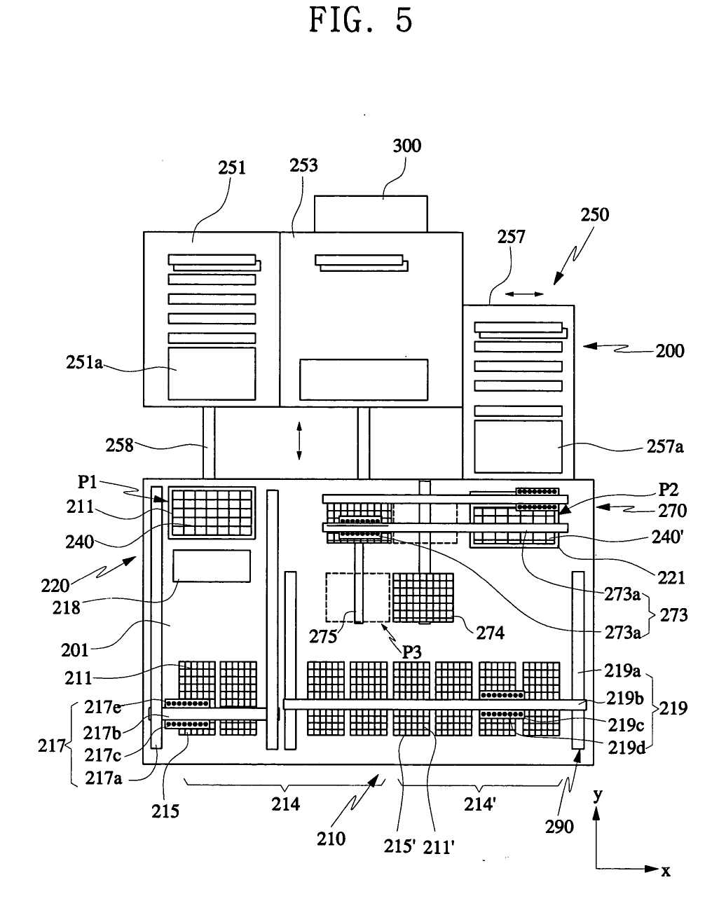

The stacker 210 includes a user tray feeder for loading the devices to be tested and a user tray sender for loading the devices tested already in accordance with the test (the user tray feeder and the user tray sender are denoted by 214 and 214′ in FIGS. 5, 6, 8 and 9 for simplicity of explanation).

Since the user tray feeder 214 and the user tray sender 214′ have the same construction, their uses are interchangeable as described while referring to FIG. 3.

As shown in FIGS. 3a-e, a number (e.g., 4) of the user tray feeders 214 are configured before a test is performed, and the remaining user tray feeders 214 are configured as user tray senders 214′. For simplicity of the explanation, the 4 user tray feeders already configured are denoted by L1, L2, L3 and L4 and the user tray feeders configured as user tray senders 214′ are denoted by UL1, UL2, UL3 and UL4.

Test operation is performed by providing a user tray 211 containing devices to be tested from the four user tray feeders L1, L2, L3 and L4, as shown in FIG. 3a. In performing the test operation, the user tray 211 is loaded on the user tray feeder L4 and is fed to and tested in a test chamber. A user tray 211′ containing the tested and sorted devices is loaded on the user tray feeders configured as user tray senders UL1, UL2, UL3 and UL4, as shown in FIG. 3b. If subsequent test operations show that the user tray feeder L4 is emptied, as shown in FIG. 3c, the user tray feeder L4 is reconfigured to be a new user tray sender UL5, as shown in FIG. 3d. By performing subsequent test operations, the user tray 211′ containing tested devices is loaded on the newly configured user tray sender UL5, as shown in FIG. 3e.

As described above, the stacker 210 is not a fixed part of the user tray feeder 214 or part of the user tray sender 214′. Moreover, the use of the stacker 210 may change as the test process progresses. As a result, the stacker 210 may be more efficiently used despite its space limitations without increasing the net resources allocated to user tray senders and user tray feeders.

While in the above example, the total number of user tray feeders and user tray senders is 8 and the number of user tray feeders used is four, the total number of user tray feeders and user tray senders need not be limited to a total of eight. Moreover, the number of user tray feeders need not be limited to a total of four.

Referring to FIGS. 1 and 2, the stacker 210 includes the user tray feeder 214 and the user tray sender 214′ which have tray support frames 213 and 213′, respectively. The user tray feeder 214 and the user tray sender 214′ prepare spaces in which the user trays 211 and 211′ are loaded. The tray support frames 213 and 213′ include a loading and an unloading set plate 215 and 215′ which perform ascending and descending operations. The user tray 211 mounted on the loading set plate 215 is drawn from an upper loading window 201a of a main body of the test apparatus 201 and is in stand-by status. The devices to be tested, which are mounted on the user tray 211 are first transferred to a preciser 218 using a loading robot 217 where positions of the devices to be tested are corrected. The devices to be tested, which have been transferred to the preciser 218, are reloaded, using the loading robot 217, onto a test tray 240 which is in a stopped loader P1.

In an example embodiment, the loading robot 217 includes two rails 217a mounted on an upper portion of the main body 201, a movable arm 217b which moves horizontally between the test tray 240 and the user tray 211 that is drawn through the loading window 201a. The movable arm 217b moves using the two rails 217a. The loading robot 217, additionally includes a movable head 217c which is supported by the movable arm 217b which moves along the movable arm 217b in a direction perpendicular to the movable arm 217b movement.

The movable head 217c has an adsorption head 217e mounted downward from the adsorption head 217e. The adsorption head 217e adsorbs the devices to be tested from the user tray 211 by sucking in air and reloads the devices to be tested on the test tray 240.

The test tray 240 is mounted on a test tray transporter 221 which moves along the direction of the X-axis shown and rests on the loader P1 while in a stand-by state. The test tray transporter 221 is carried to an unloader P2 of a sorter 270 along a transporting rail later described.

The test tray 240 is loaded with the devices to be tested in the loader P1 and is moved to the chamber 250. The devices to be tested are tested in the state that they are mounted on the test tray 240.

The chamber 250 includes a soak chamber 251, a test chamber 253 and a desoak chamber 257. The soak chamber 251 exposes the devices to be tested to stress at a high or low temperature. The test chamber 253 tests the devices after exposure to stress in the soak chamber 251. The desoak chamber 257 cools devices exposed to high temperatures in the test chamber 253 and heats devices exposed to low temperatures in the test chamber 253. In most cases, devices are exposed to extreme heat while in the test chamber 253.

As shown in FIG. 5, inverters 251a and 257a are included in the soak chamber 251 and the desoak chamber 257, respectively, which vertically position the test tray 240 from a horizontal position.

The chamber 250 can be separated from the main body 201 as shown in FIGS. 3 and 4. The soak chamber 251 and the test chamber 253 may be constructed as one body, which can be separated from the main body along the Y-axis shown. The desoak chamber 257 may be constructed to separate along the X-axis shown.

A sliding apparatus 258 may be employed to separate the chambers, which is constructed as a LM (Linear Motion) guide or the like. Since the chambers are constructed to separate from the main body, it is easy to check and repair various mechanical and circuit parts included in the main body 201. While the above example embodiment discloses the desoak chamber 257, soak chamber 251, and test chamber 253 being separable from the main body 201, one skilled in the art would recognize that various combinations of separation of the desoak chamber 257, desoak chamber 251, and test chamber 253 from the main body 201 may be used to obtain the benefits of the invention.

Referring to FIGS. 1 and 2, the test tray 240′ used during testing and in the desoak chamber 257 is transfered to the unloader P2 from the desoak chamber 257. When the test tray 240 on the test tray transporter 221 is drawn into the soak chamber 251, the test tray transporter 221 on the loader P1 is carried to the unloader P2 and is in stand-by status. Accordingly, the test tray 240′ tested stays on the test tray transporter 221 and then is carried to each sorter table 274 sorted by a sorting robot 273. Here, since a receiver of the sorter table 274 has an associated area to receive the devices according to test grade, the sorting robot 273 stops in a position where it adsorbs the devices on the test tray 240′ for sorting.

The sorting robot 273 includes an X-axis guide rail 273a and a variable hand 273b moving along the X-axis guide rail 273a, the guide rail and the variable hand being a pair.

The sorter table 274 is installed on a lead screw 275 placed in the direction of Y-axis to be moved in the direction of Y-axis. When the devices are carried by the test tray 240′ from the test tray 240′ to the sorter table 274, the test tray transporter 221 having a vacant test tray 240′ on it is carried to along the X-axis again and is in the stand-by status in the loader P1.

Referring to FIGS. 1 and 2, when the sorter table 274 moves to a device unloading position P3, an unloading robot 291 picks up the devices loaded on the sorter table 274 and carries them to the user tray sender 214′ of the stacker 210. Here; the unloading robot 291 includes two rails 291a mounted on the main body 201; the unloading robot having similar structure as the loading robot 217. The unloading robot 291 further includes a movable arm 291b which moves along a Y-axis, as shown, between the sorter table 274 and the user tray 211′ mounted on an unloading set plate 215′ of the user tray sender 214′ along the two rails 291a and 291a, and a movable head 291c which moves along an X-axis as shown supported by the movable arm 291b. The movable head 291c has an adsorption head 291e mounted downward, and the adsorption head 291e carries the devices which are sorted and kept in the sorter table 274 to the user tray sender 214′ which is divided in accordance with unit quantity, kinds, and grades. When the devices are carried and loaded onto the user tray 211′, the user tray 211′ having been placed in the loading set plate 215 of the user try sender 214, and fill the user tray 211′, the user tray 211′ descends to the inner part of support fame 213′ of the user tray sender 214′ and is loaded on the support frame 213′.

Increasing the Quantity of Devices that Can Be Tested

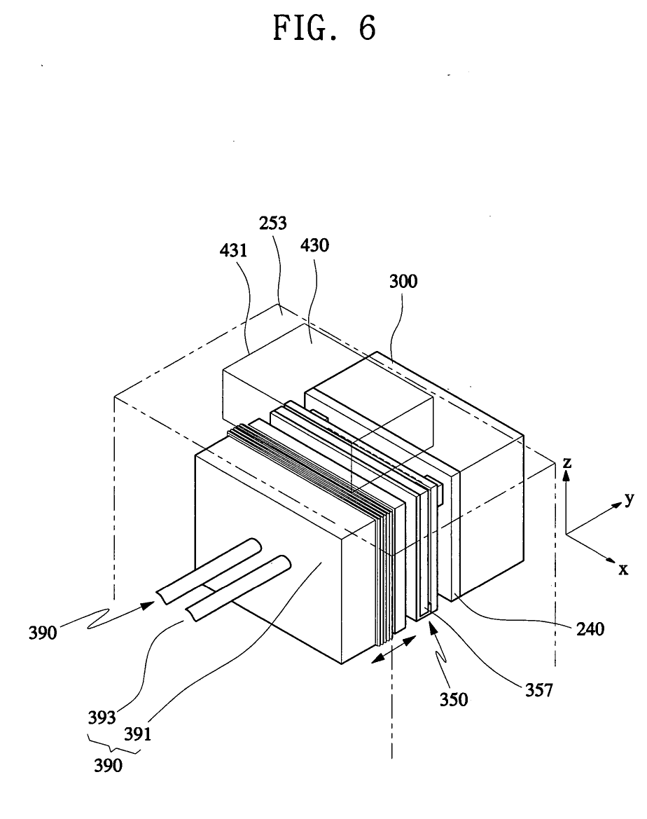

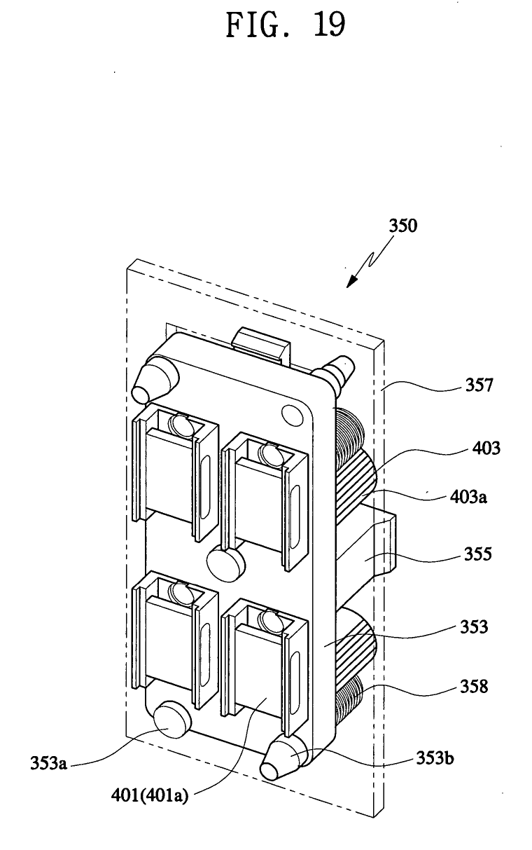

In another example embodiment of the invention, an insert 330 of the test tray 240 and a load pusher assembly 350 and a socket assembly 310 of the test head 300 are provided that aid in an increase the quantity of devices that can be tested in a unit time. This example embodiment has the same constructions for test handlers as shown in FIGS. 1 to 5. This embodiment is described with reference to FIGS. 6-19.

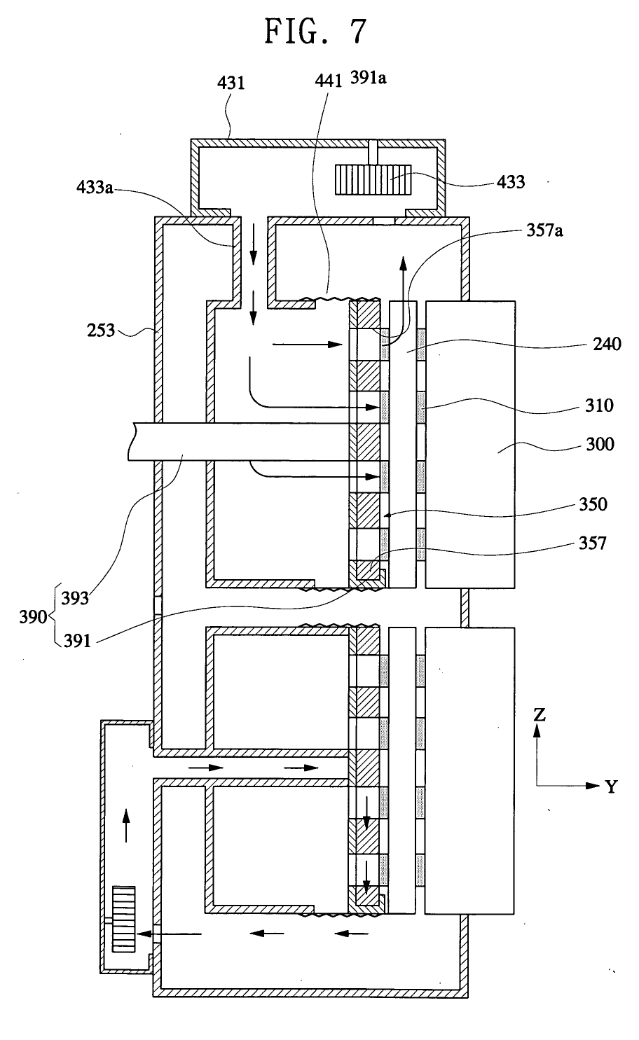

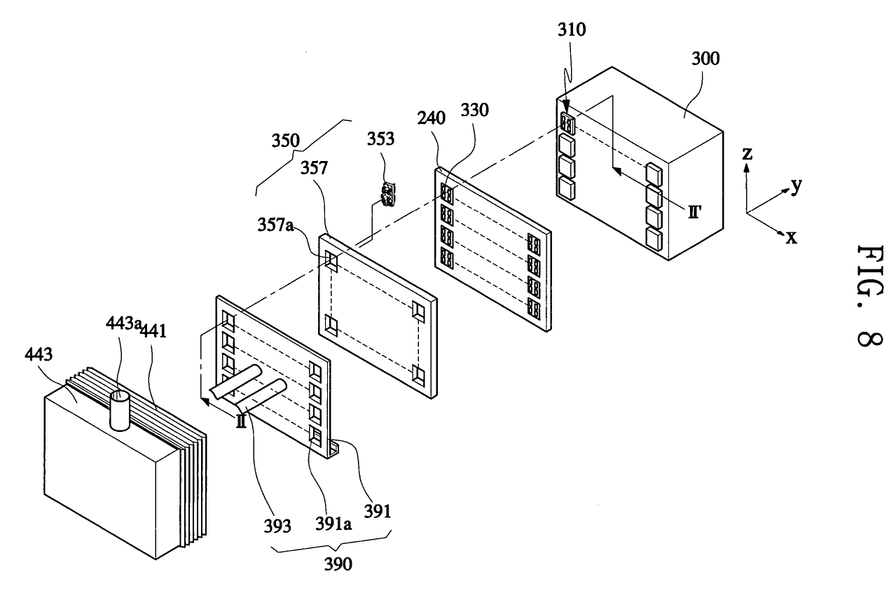

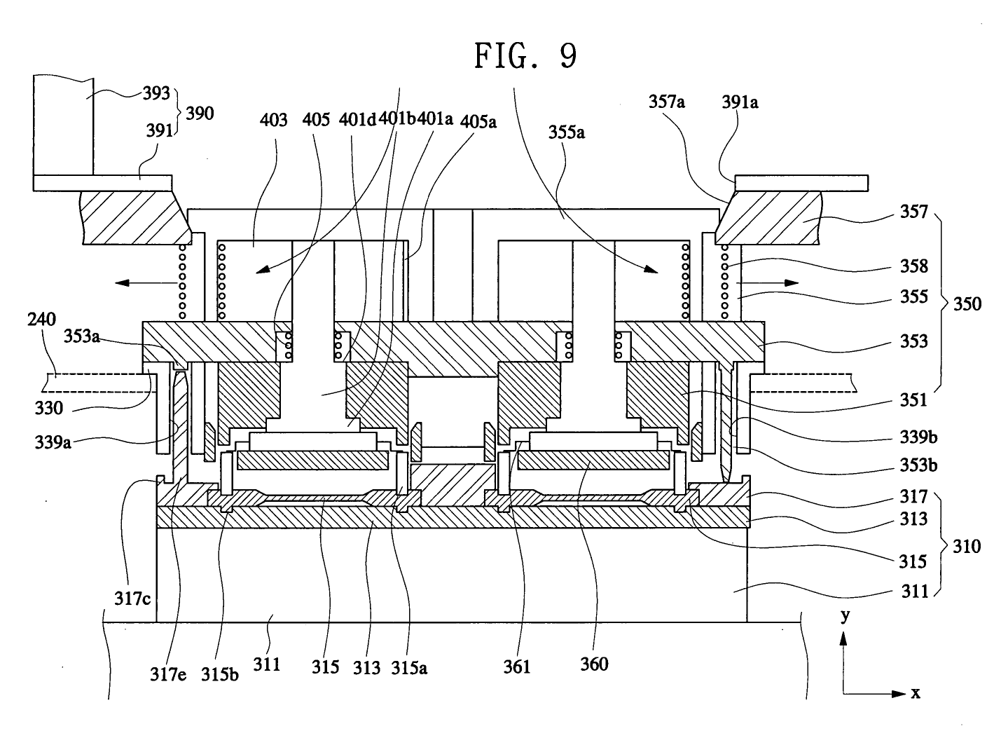

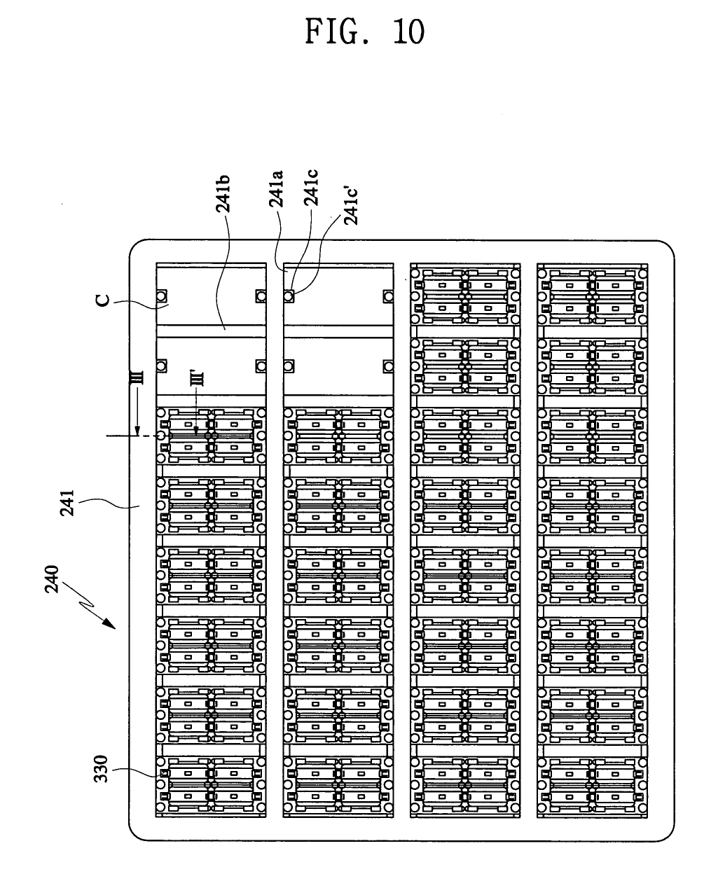

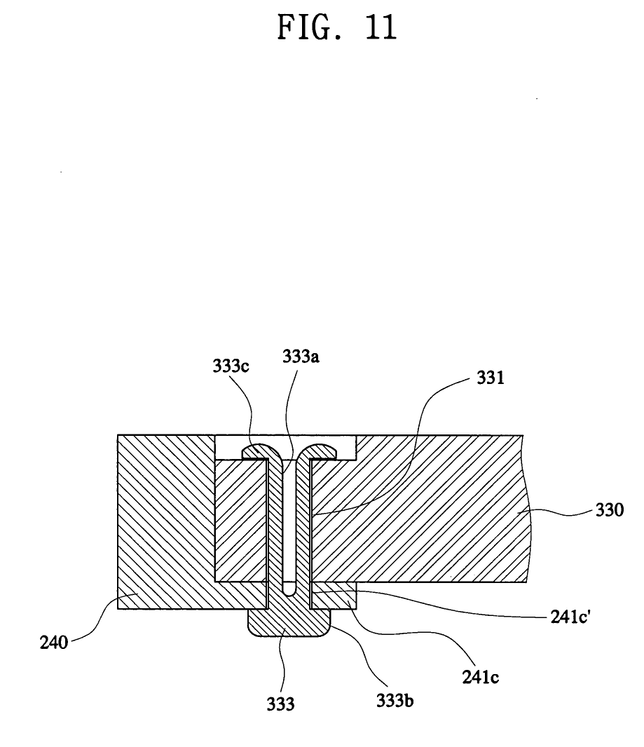

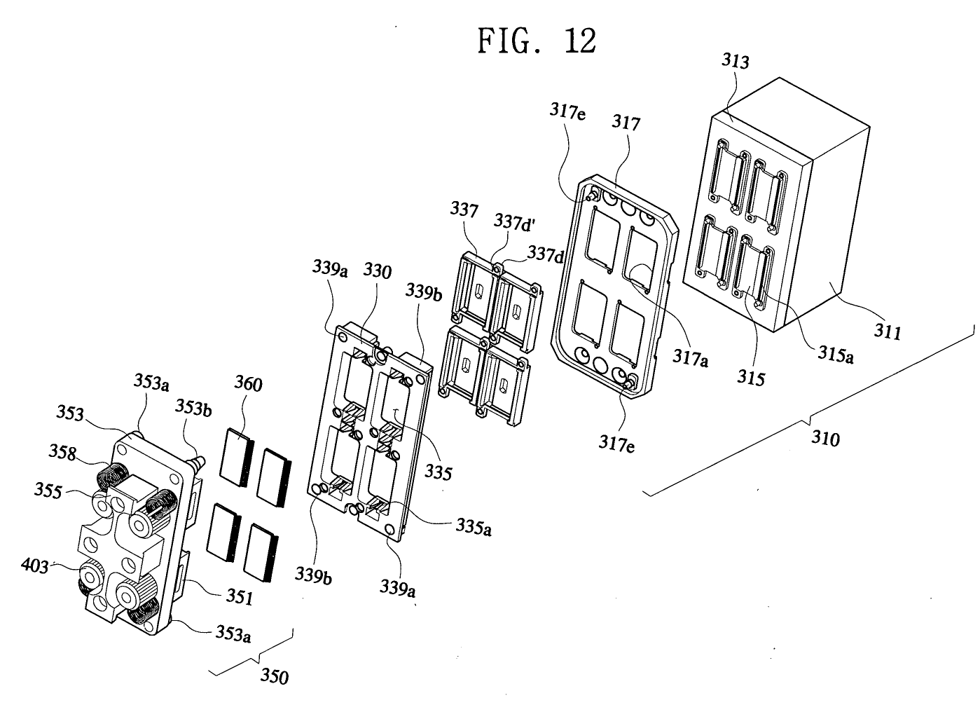

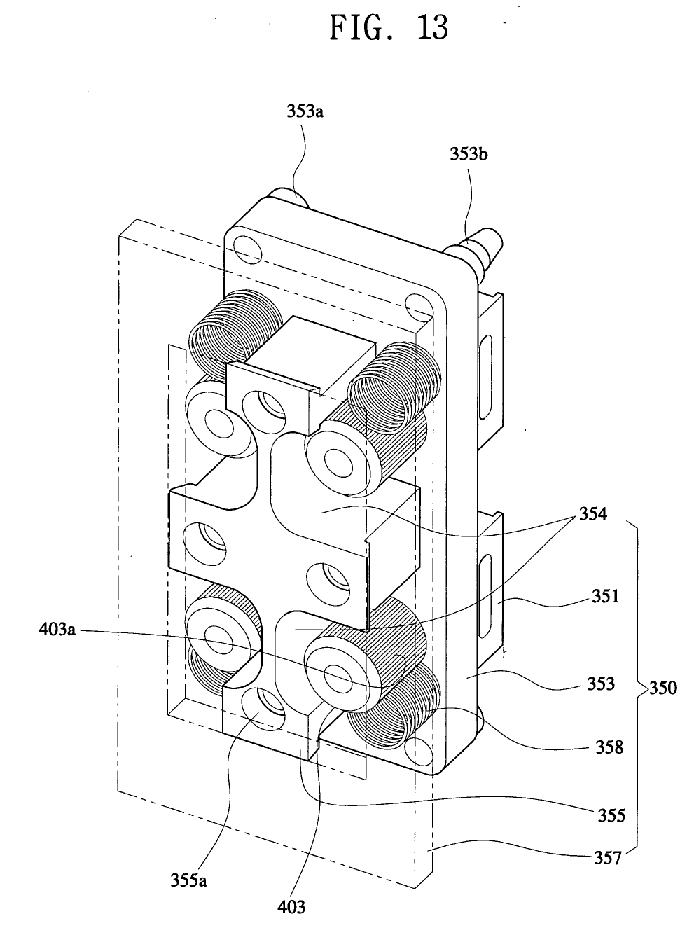

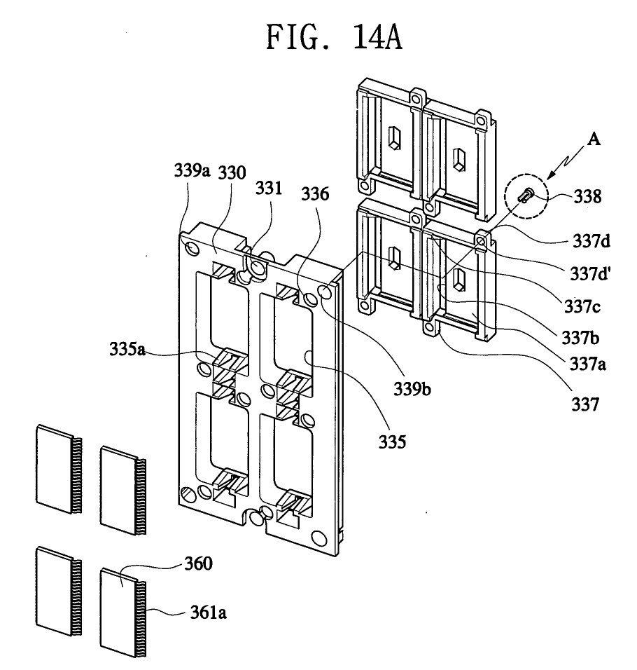

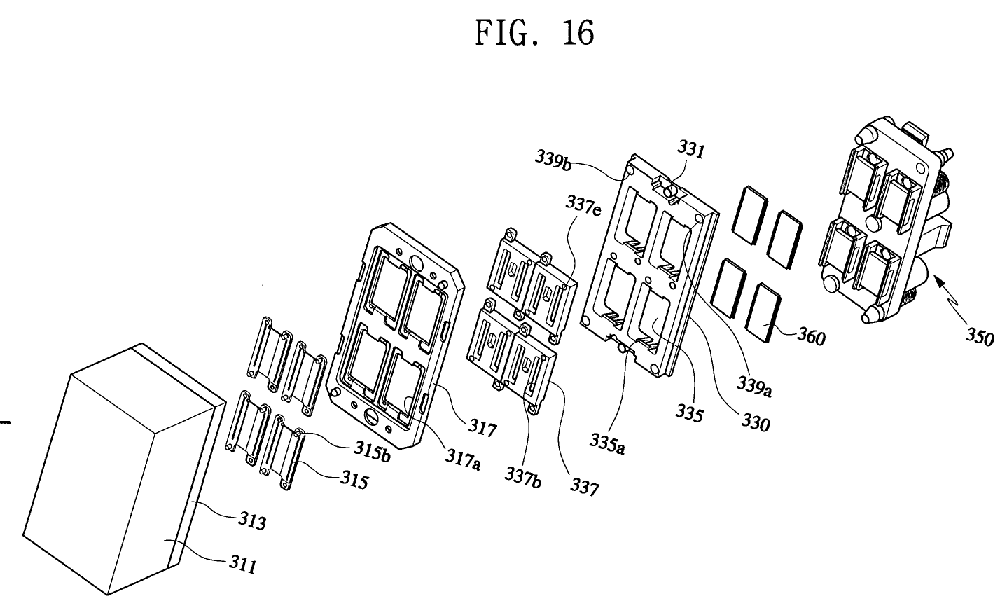

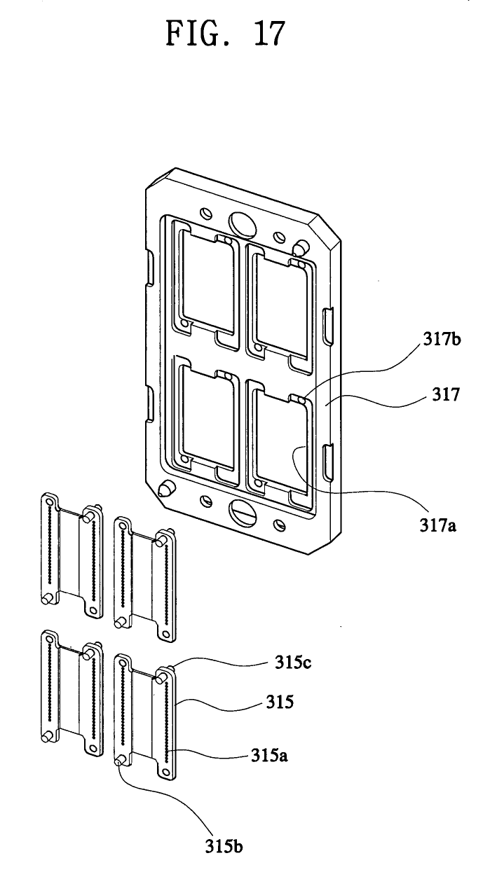

FIG. 6 is an example perspective view showing an upper part of a test chamber in accordance with an example embodiment of the invention; FIG. 7 is an example sectional view of the semiconductor device test apparatus of FIG. 4 in accordance with an example embodiment of the invention; FIG. 8 is an example exploded view of part of the semiconductor device test apparatus shown in FIG. 6 in accordance with an example embodiment of the invention; FIG. 9 is an example sectional view of a portion of the semiconductor device test apparatus of FIG. 8 in accordance with an example embodiment of the invention; FIG. 10 is an example plane view showing a test tray in accordance with an example embodiment of the invention; FIG. 11 is an example sectional view of part of the test tray shown in FIG. 10 in accordance with an example embodiment of the invention; FIG. 12 is an example perspective view showing parts of FIG. 9 in accordance with an example embodiment of the invention; FIGS. 13 to 15 are example magnified views of parts of FIG. 12 in accordance with an example embodiment of the invention; FIG. 16 is an example separated perspective view of parts shown FIG. 9, which is viewed from the opposite direction of FIG. 12 in accordance with an example embodiment of the invention; and FIGS. 17 to 19 are example magnified views of parts of FIG. 16 in accordance with an example embodiment of the invention.

Referring to FIGS. 6 to 8, a test chamber 253 includes a test head 300, a test tray 240, a lead pusher assembly 350 and a driving unit 390.

As shown in FIG. 8, a plurality of socket assemblies 310 are placed on a test head 300 at desired intervals in the form of a matrix. Referring to FIG. 12, the socket assemblies 310 include a socket block 311 mounted on the test head 300, a circuit board 313 mounted on an upper part of the socket block 311, a plurality of sockets 315 placed on the circuit board 313, for example, in a matrix having 2 rows and 2 columns, and a socket guide 317 covering an upper part of the circuit board 313 and preparing a plurality of windows 317a to pass a contact pin 315a of the socket 315 through. Also, as shown in FIGS. 13, 16 and 19, a pocket position determination pin 315c is formed on the test head 300, which passes through and is inserted into a through hole 317b formed in the socket guide 317. The pocket position determination pin 315c acts to determine the position of the socket guide 317 and is inserted into a position determination groove 337e formed on the bottom of a pocket 337 to be described later to determine the position of the pocket 337. A reinforcement rib 317c is formed to project on an upper edge of the socket guide 317. The socket assembly 310 is constructed on the test head 300 in 4 rows and 8 columns, for example, so that it is possible to test 128 devices simultaneously. As shown in FIG. 17, the socket 315 has a fixing protrusion 315b on its lower part, the protrusion being inserted into the circuit board 313.

While 128 devices may be tested using an example embodiment of the invention, more or fewer devices may be tested with larger or smaller embodiments of the invention.

The test tray 240 receives inserts 330 to house the devices to be tested as shown in FIGS. 10 and 11, and has a rectangular frame 241 in which a number of sub-frames 241a and 241b are formed as a form of lattice. The space C formed on the sub-frame of the lattice is a place on which the inserts 330 are loaded, and the arrangement of the space C is the same as that of the socket assembly 310, for example, 4 rows and 8 columns. A mounting piece 241c having an insert fixing hole 241c′ is arranged in both sides of the sub-frame 241a. The inserts 330 have a fixing hole 331 which is connected to the insert fixing hole 241c′ as shown in FIG. 11 and both holes are fixed with an insert fastener 333. The insert fastener 333 is formed of a cylindrical shape which has a forked part 333a in its central part and has a stopper 333b which makes contact with the bottom of the mounting piece 241c and is stopped, and a hook 333c which passes through the fixing hole 331 and is hooked on the upper surface of the insert 330.

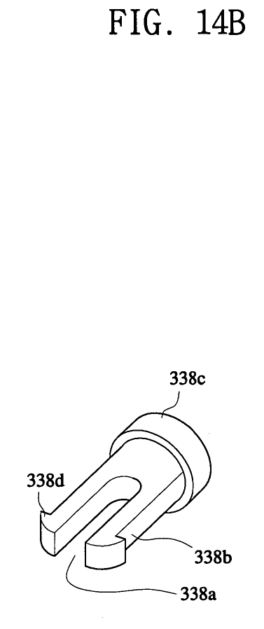

The insert 330 has an insert receiver 335 in an arrangement of 2 rows and 2 columns, which is the same arrangement construction as that of the socket 315 as shown in FIG. 14a. The pocket 337 receives the devices 360 and is mounted in the insert receiver 335. The pocket 337 has a rectangular box shape and an opened top to receive the devices 360. A long lead through hole 337b is formed in both sides of the bottom surface 337a in order that a lead 361 of the devices 360 may pass through the through hole. A first guider 337c is arranged on the other side of the lead through hole 337b, which guides the loading operation of the device 360. A second guider 335a is arranged in the insert 220, which is contacted with both ends of the pocket 337. The above construction allows for a proper positioning and safe mounting of the devices 360.

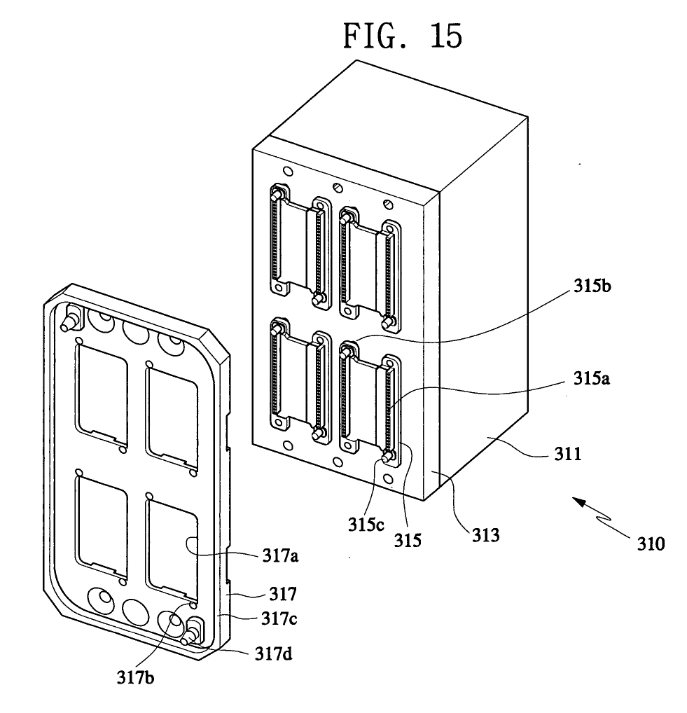

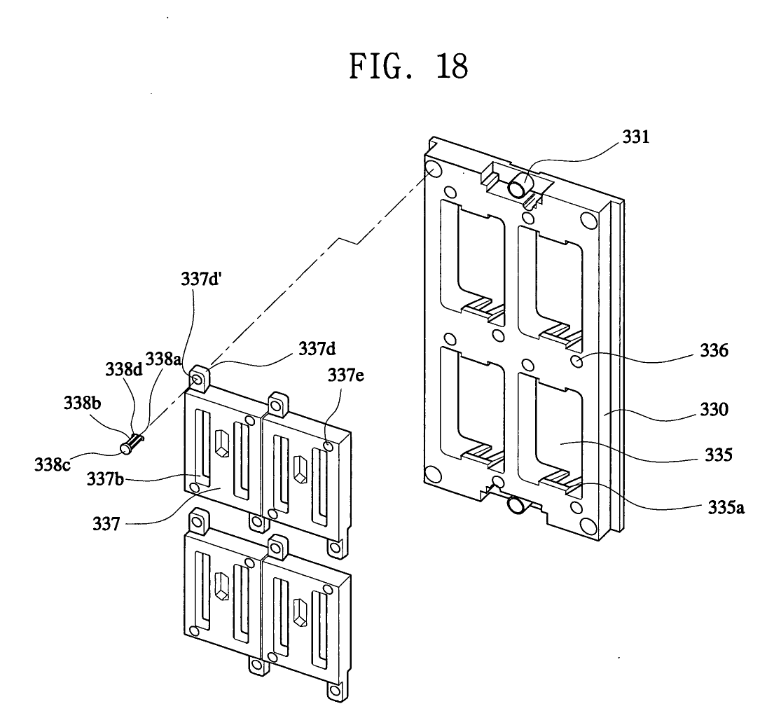

The relationship between the pocket 337 and the insert 330 is as follows. Referring to FIGS. 14a and 18, the pocket 337 has a fixing piece 337d in both ends of it, which has a through hole 337d′ formed in diagonal direction. A fixing hole 336 is formed in the insert 330, which is aligned with the thorough hole 337d′ of the fixing piece 337d. And, a pocket fastener 338 is inserted through the through hole 337d′ and the fixing hole 336 and fixes the pocket 337 into a stable position. The pocket fastener 338 has the same construction with that of the insert fastener 333 shown in FIG. 15. As shown in FIG. 14b, it is formed of a cylindrical body 338b having a forked part 338a in its central part and a stopper 338c. The stopper's 338c lower part is stopped on the bottom of the insert. A hook 338d is formed on the upper part of the forked part 338a. The forked part 338a goes through the fixing hole 336 and the through hole 337d′, and is contracted. After the forked part 338a passes through the fixing hole 336 and the through hole 337d′, the hook 338d is hooked on the upper part of the insert 330 and fixed. An outer diameter of the body 338b of the pocket fastener 338 is formed smaller than an inner diameter of the fixing hole 336 and the through hole 337d′ so that some flexibility is given when the pocket 337 is fixed to the insert 330. The configuration helps guide a determination of contact position between the devices 360 and a contact pin 315a of the socket 315. On the opposite side of the side in which the fixing piece 337d of the pocket 337 is formed, a position determination groove 337e is formed as shown in FIG. 18 and a pocket position determination pin 315c formed on the socket 315 shown in FIG. 15 is inserted into the groove.

As shown in FIG. 9, the lead pusher assembly 350 and the driving unit 390 include a pusher 351 pressing a lead 361 of the devices 360 that are safely mounted on the pocket 337, a pressure plate 353 that contacts an upper part of the pusher 351, a contact block 355 installed on the pressure plate 353 and a match plate 357 contacted with an upper part of the contact block 355, and a first resilient member 358 installed between the match plate 357 and the pressure plate 353. On the other hand, the driving unit 390 includes a driving plate 391 installed in the rear of the match plate 357, and at least one driving axis 393 installed in the rear of the driving plate 391. The first resilient member 358 is a compression spring maintaining the pressure plate 353 as an extension state when the driving plate 391 is not driven. When the match plate 337 contacted with the driving plate 391 moves forward to the test head 300 and then the lower part of the pusher 351 presses the lead 361, the pusher 351 presses the lead at a desired pressure.

A construction restricting a position where the match plate 357 moves forward is explained with reference to FIG. 9. The construction includes a plurality of first and second pressure plate protrusion pins 353a and 353b formed on the bottom of the pressure plate 353, a first and a second position determination holes 339a and 339b formed around the insert 330 to make the pressure plate protrusion pins 353a and 353b inserted, and a socket guide protrusion pin 317e formed on the upper surface of the socket guide 317 to be contacted with the bottom of the first pressure plate protrusion pin 353a. Here, the second pressure plate protrusion pin 353b is as long as to be contacted with the upper surface of the socket guide 317, and the length of the first pressure plate protrusion pin 353a becomes the length of the socket guide protrusion pin 317e plus the length of the second pressure plate protrusion pin 353b. Due to the construction described above, the pressure length of the lead pusher assembly 350 is restricted and a position alignment of the lead pusher assembly 350 with the lead pusher assembly 350, the insert 330 and the socket assembly 310 is guided. Accordingly, each contact pin 315a of lead 361 of the devices 360 obtains a good contact.

As described above, after the device receiver 335 of the insert 330, the socket 315 of the socket assembly 310 and the pusher 351 of the lead pusher assembly 350 are arranged in 2 rows and 2 columns, and its unit insert 330, the socket assembly 310 and the lead pusher assembly 350 are arranged in 4 rows and 8 columns, 256 devices which are contacted with two test heads 300 arranged in two sections and loaded on the test tray 240 are tested simultaneously. Due to this construction, it is possible to simultaneously test twice as much as those of 128 devices being the numbers to be tested in a unit time.

Temperature Control

Another example embodiment of the invention is the same as the second example embodiment of the invention except that a construction of a temperature control ventilation apparatus 430 and a heat sink 403 for cooling the devices 360 in a heat conduction method are employed. Detailed construction of this example embodiment will be explained with reference to FIGS. 6 to 9, 13, and 19.

A construction in which the heat of the devices 360 is cooled using a conduction method is shown in FIG. 9. As shown in FIG. 9, a conductor 401 is positioned through the inner part of the pusher 351 so that the upper part of the conductor 401 goes through the pressure plate 353. The conductor 401 includes a device contact part 401a whose bottom is formed of a rectangular plate type corresponding to the devices and a support axis 401b which is formed to erect on the upper surface of the device contact part 401a, the upper part of the support axis 401b being connected to a heat sink 403. The support axis 401b has its end part 401d, and a second resilient member 405 is installed outside the support axis 401b going through the inner part of the pressure plate 353. The second resilient member 405 is a compression spring, which maintains an extension state when the lead pusher assembly 350 is not pressed and presses the device 360 at a desired pressure when the lead pusher assembly 350 is pressed so that the device contact part 401a is contacted with the upper part of the device 360.

Referring to FIG. 13, the heat sink 403 is formed of a cylindrical body having a number of prominences and depressions 403a around it to increase a heat radiation area. The heat sink 403 helps to radiate the heat of the devices 360 conducted from the conductor 401. In addition, a contact block 353, having the heat sink 403 internally, has a penetrating part 354 whose upper surface and four-sides are opened in order to form a passage for air to be blown from a temperature control ventilation apparatus 430 to be explained later.

To ventilate the heat sink 403 with temperature control air, the temperature control ventilation apparatus 430 is installed on a lower rear side of the test chamber 253 as shown in FIGS. 6 and 7. The temperature control ventilation apparatus 430 has a fan 433 and a heat exchanger (not shown) inside a case 431. The temperature control ventilation apparatus 430 sucks air from inside the test chamber 253 using the fan 433 and discharges it outside of the test chamber 253 using the heat exchanger so that inside of the test chamber 243 is kept in a desired temperature condition (high or low temperature). The air circulation construction described above includes a match plate 357 with a plurality of air passage holes 357a. A driving plate 391 installed in the rear of the match plate 357 has a plurality of air passage holes 391a in the position corresponding to the air passage holes 357a.

To guide temperature controlled air supplied from the temperature control ventilation apparatus 430, a flexible duct 441 contacted with both sides of the driving plate 391 is installed in the rear of the driving plate 391 as shown in FIGS. 6, 7 and 8. The flexible duct 441 is a duct having a rectangular and having both ends opened, one end of it being contacted with the four-side of the driving plate 391. The reason to employ the flexible construction is to provide a construction where the driving plate 391 can face forward and backward movement operations flexibly. A fixing duct 443 is installed in the other end of the flexible duct 441. The fixing duct 443 is installed at a desired position with one end inserted into the flexible duct 441. The fixing duct 443 is a rectangular box shape having one surface opened. The opened surface communicates with the flexible tube 441. The fixing duct 443 is connected to a connection duct 433a which communicates with the temperature control ventilation apparatus 430.

An operation to control the temperature of the device 360 using the above construction is now described.

Initially, when the device 360 is tested in the state that it is contacted with a contact pin 315a of the socket 315, the device 360 radiates heat. In this position, the heat of the device 360 is conducted through the conductor 401 that is contacted with the upper surface of the device 360, and the conductor 401 is connected to the heat sink 403 so as to release the heat conducted. Additionally, the temperature controlled air which is discharged through the temperature control ventilation apparatus 430 flows into the fixing duct 443 and the flexible duct 441 through the connection duct 443a. The air further flows into the heat sink 403 by way of an air through hole 391a of the driving plate 391 and an air through hole 357a of the match plate 357. The flowed air again is discharged into the site of the temperature control ventilation apparatus 430. Here, the contact block 355 shown in FIG. 13 that is installed around the heat sink 403 has a through hole 355a so as to favorably circulate the air. The temperature control ventilation apparatus 430 causes air to flow in contact with the heat sink 403, and the device 360 to help control the temperature of the device during a testing cycle

Therefore, it is possible to cool the highly heated device 360 efficiently by the device 360 directly making contact with the construction described above and controlling the temperature with the heat conduction method.

Loading Robot Automatic Speed Control

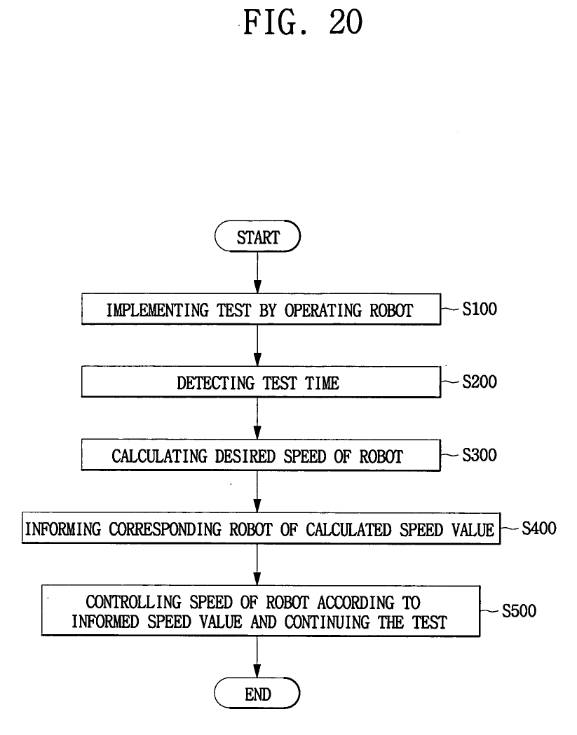

FIG. 20 is a flow chart showing an example of how to automatically control speeds of a loading robot 217, a sorting robot 273 and an unloading the robot 291 shown in FIGS. 1, 2, 4 and 5. The flow chart shows an example method of how to automatically control the speeds of the robots 217, 273 and 291 in connection with testing time to more efficiently use the robots and reduce fatigue. A description of the example flow chart of FIG. 20 follows.

Initially, a test is implemented by operating the robots 217, 273 and 291 (S100), and the time of the test performed in the chamber 253 is detected (S200). By performing a comparison and a determination using a detected test time, each driving speed for each robot 217, 273 and 291 corresponding to the test times is calculated (S300) and each robot 217, 273 and 291 is assigned newly designated speed values (S400). Then, each robot 217, 273 and 291 operates using the newly designated speed values and continues to implement the test (S500).

The detection of the test time is implemented by checking the points at which the device 360 of the test tray 240 makes contact with the test head 300 and is separated from the test head 300 and calculating the time between them. In another method for detecting the test time, each device is tested and each test time is stored in a special database so that the value of the test time corresponding to each device may be provided to test subsequent like devices.

### CONCLUSION

As described above, example embodiments of the invention provides stacker operations allowing user tray feeders to function like user tray senders and user tray senders to function like user tray feeders.

Example embodiments of the invention, further, help make checking and repairing an interior of a main body easier using a construction capable of dividing a chamber from the main body. Moreover, example embodiments of the invention allow a quantity of devices tested per a unit time to be increased by enhancing an insert construction stacked on a test tray and by enhancing a construction of a test head and a lead pusher assembly. Still further, example embodiment of the invention help prevent a problem where a robot operates at an unnecessarily high speed causing unnecessary a fatigue of a robot over a long time.

Moreover, in example embodiments of the invention, the cooling of a device is enhanced by adopting a heat conduction method where the device is directly in contact with a cooler so that the temperature increase around the device caused by a self-heating of the device can be reduced or prevented.

Although the preferred embodiments of the present invention have been disclosed for illustrative purposes, those skilled in the art appreciate that various modifications, additions and substitutions are possible, without departing from the scope and spirit of the invention as disclosed in the accompanying claims. The hardware disclosed, for example, is specifically disclosed. Other equivalent hardware and hardware configurations could be used as would be known to one of ordinary skill in the art to obtain the benefits of the invention.

1. A semiconductor device test apparatus comprising:
a main body;
a soak chamber;
a test chamber;
a desoak chamber;
wherein the soak chamber, the test chamber, and the desoak chamber can be separated from the main body.

2. The semiconductor device test apparatus of claim 1 wherein the soak chamber, the test chamber, and the desoak chamber can be separated from the main body using a sliding unit.

3. A semiconductor device test apparatus comprising:
a main body; and
a stacker for stacking devices before and after a test, the stacker including user trays for stacking the devices, the user trays being interchangeable such that the user trays may be used to stack the devices prior to the test and to stack the devices after the test.

4. The semiconductor device test apparatus of claim 3, wherein the user trays are interchanged in accordance with the process of the test.

5. A semiconductor device test apparatus comprising:
a main body;
a stacker for stacking devices before and after a test, the stacker including at least one user tray feeder predesignated with a function for stacking un-tested devices and at least one user tray sender predesignated with a function for stacking tested devices, the user tray functions being interchangeable during stacker operation.

6. A semiconductor device test apparatus comprising:
a main body; and
a stacker arranged in the main body, the stacker having a user tray feeder which loads a plurality of user trays having a desired quantity of devices to be tested and a user tray sender which loads the plurality of user trays having the devices sorted by their grades in accordance with the test result, the user tray feeder and the user tray sender being interchanged in their uses in accordance with the process of the test.

7. The semiconductor device test apparatus of claim 6 further comprising:
a soak chamber for receiving the test tray inputted from the device loader, and for preheating or precooling the devices;
a test chamber for connecting the preheated devices in the soak chamber to a socket of a test head and for performing a test;
a desoak chamber for receiving the test tray discharged from the test chamber and for discharging them to a device unloader after recovering them to a room temperature;
wherein the soak chamber, the test chamber and the desoak chamber can be separated from the main body using a sliding unit.

8. The apparatus according to claim 7, wherein the soak chamber and the test chamber are made of one body to be separated in the same direction.

9. The apparatus according to claim 7, wherein the desoak chamber is able to be separated in same direction as the separation direction of the soak chamber and the test chamber.

10. The semiconductor device test apparatus of claim 6 further comprising:
a loading robot for picking up devices to be tested which are in a stand-by status in the user tray feeder and mounting them on a test tray being on a device loading stage;
a sorting robot for picking up the device discharged to the device unloader and for carrying them to a plurality of sorter tables in accordance with the test result; and
an unloading robot for picking up the device carried to the sorter table and for carrying them to the user tray sender.

11. A semiconductor device test apparatus comprising:
a test chamber for providing desired test space;
at least one test head installed on one side of the test chamber;
a socket assembly having a socket block and a plurality of socket guides, the socket block being arranged on the test head at a desired interval in a matrix form and having a plurality of sockets contacted with a plurality of devices, the socket guide covering an upper part of the socket block and having a plurality of socket guides provided with a plurality of windows to pass through a contact pin of the socket;
a test tray for loading a plurality of inserts and for arranging the inserts in a matrix form corresponding to the arrangement form of the socket, the inserts having a plurality of device receivers to receive devices corresponding to the plurality of sockets; and
a lead pusher assembly having a match plate, a plurality of pressure plates and a plurality of pushers, the match plate being arranged in parallel with the test head and being connected to a driving unit, the pressure plates being arranged in the match plate through a contact block in a matrix form corresponding to the insert arrangement form, the pushers being arranged in a side of the pressure plate and pressing a lead of the device.

12. The apparatus according to claim 11, wherein the socket assembly includes four sockets, the insert includes four insert receivers, and the pressure plate includes four pushers, the sockets, inserts and pushers being arranged in 2 rows and 2 columns.

13. The apparatus according to claim 12, wherein a protruded fixing piece having a through hole is formed on both ends of the pocket; the apparatus further including:
a fixing hole that communicates with the through hole of the fixing piece, the fixing hole being part of the insert; and
a pocket fastener having a cylindrical body, the cylindrical body having a forked part
a stopper, the stopper being inserted into the through hole and the fixing hole, the stopper being formed under the body and being stopped under the bottom of the insert; and
a hook, the hook being inserted into the through hole and the fixing hole, the hook being formed on the body and being hooked on the upper surface of the pocket.

14. The apparatus according to claim 12, wherein a first guider is formed around four sides of an inner part of the pocket; and
a second guider to guide a loading operation of the devices, the scond guider being formed in both ends of the insert receiver.

15. The apparatus according to claim 11, wherein the socket assembly, the insert, and the pressure plate are arranged on the test head, the test tray and the match plate in four rows and eight columns, respectively.

16. The apparatus according to claim 15, wherein the pocket fastener is formed to have an outer diameter of the body smaller than inner diameters of the through hole and the fixing hole so as to give flexibility to the pocket.

17. The apparatus according to claim 11, wherein the insert receiver has a pocket which receives the devices.

18. The apparatus according to claim 17, wherein the socket has a fixing protrusion on its lower part and a pocket position determination pin on its upper part, the protrusion being inserted into the socket block, the pocket position determination pin passing through the through holes formed around the window of the socket guide; and
a position determination groove arranged on the lower part of the pocket, into which the pocket position determination pin is inserted.

19. The apparatus according to claim 18, wherein the first resilient member is a coiled compression spring.

20. The apparatus according to claim 18, wherein a plurality of first and second position determination holes are formed in sides of the insert;
first pressure plate protusion pins and second pressure plate protrusion pins that are inserted into the first and the second position determination holes, first pressure plate protusion pins and second pressure plate protrusion pins formed in the four sides of the pressure plate; and
a socket guide protrusion pin which is inserted from the lower part of the first position determination hole, the socket guide protrusion pin is formed on the upper part of the socket guide.

21. The apparatus according to claim 11, further comprising a first resilient member arranged between the match plate and the pressure plate.

22. The apparatus according to claim 21, wherein a length of the second pressure plate protrusion pin inserted into the second position determination is long enough such that the second pressure plate protrusion pin contacts the upper surface of the socket guide; and
a length of the first pressure plate protrusion pin is long enough such that the the total length of the first pressure plate protrusion pin and the socket guide protrusion pin, together, that are inserted into the first position determination hole are the same length as the second pressure plate protrusion pin.

23. The apparatus according to claim 11, wherein a protruded reinforcement rib is formed in an upper edge of the socket guide.

24. The apparatus according to claim 11, wherein their are two test heads arranged vertically.

25. A semiconductor device test apparatus comprising:
a test chamber;
at least one test head installed in one side of the test chamber;
a plurality of sockets installed on the test head;
a test tray having an insert receiving a plurality of devices to be contacted with the socket;
a lead pusher assembly including,
a pusher for pressing a lead of the device, a pressure plate on the pusher,
a contact block installed on the pressure plate, and
a match plate in contact with the upper edge of the contact block and having a plurality of through holes to open the upper edge of the contact block.
a conductor that penetrates an inner part of the pusher, the conductor making its bottom contacted with the upper surface of the device, the conductor having an upper part that passes through the pressure plate; and
a heat sink including a central and inner part that are connected to the upper part of the conductor, the heat sink radiates the heat conducted from the conductor.

26. The apparatus according to claim 25, wherein the conductor includes,
a device contact part of a first surface which is in contact with the device;
a protruded support axis on a second surface of the device contact part, the conducter passes through the upper part of the pressure plate; and
a resilient member mounted outside the support axis through which the pressure plate passes.

27. The apparatus according to claim 26, wherein the resilient member is a coiled compression spring.

28. The apparatus according to claim 25, wherein the heat sink is formed cylindrically and has a plurality of prominences and depressions on its outer surface to increase the heat dispersion area.

29. The apparatus according to claim 25, wherein the contact block has through holes on its upper surface and four side surfaces in order that air input through the through hole of the match plate is easily dispersed along the four side surfaces.

30. The apparatus according to claim 25, further including,
an air passage hole corresponding to an air passage hole of the match plate is at the rear of the match plate;
a driving plate provided with a driving axis is at the rear of the match plate;
a flexible duct opened at both ends is connected to the driving plate;
a rectangular box type fixing duct opened in its side which is connected to the flexible duct is at one end of the flexible duct; and
a temperature control ventilation apparatus inside a test chamber, the temperature control ventilation apparatus providing one side of the test chamber with temperature controlled air through the flexible duct, and making the the temperature controlled air to be input through a space between the match plate and a test tray after the temperature controlled air has contacted the heat sink.

31. A semiconductor device test apparatus comprising:
a perforated heat sink including a conductor extended from the perforated heat sink, the conductor in direct contact with a device during a testing cycle to dissipate heat from the device during the testing cycle.

32. The semiconductor device test apparatus of claim 31 further comprising:
a temperature control ventilation apparatus that causes air to flow through the perforated heat sink, contact the heat sink, contact the conductor, and contact the device to help control the temperature of the device during the testing cycle.

33. A semiconductor device test apparatus comprising:
a loading robot for picking up devices to be tested which are in a stand-by status in a user tray feeder and mounting the devices on a test tray, the test tray being on a device loading stage;
a sorting robot for picking up the device discharged to the device unloader and for carrying the device discharged to a plurality of sorter tables in accordance with the test result; and
an unloading robot for picking up the device carried to the sorter table and for carrying the device to the user tray sender;
wherein the operating speeds of the loading robot, the sorting robot, and the unloading robot is determined based on the speed of testing the device.

34. A semiconductor device test apparatus comprising:
at least one robot used in a test that receives control signals instructing the at least one robot to carry a device at a calculated speed, the calculated speed corresponding based on a time of test execution.

35. A method for constructing a semiconductor device test appartus comprising:
attaching, during manufacture, a soak chamber, a test chamber, and a desoak chamber to a main body so that the soak chamber, the test chamber, and the desoak chamber, may be later separated.

36. The method for constructing a semiconductor device test appartus according to claim 35 further comprising:
creating the soak chamber, the test chamber, and the desoak chamber with attachment configurations, the attachment configurations used to attach the soak chamber, the test chamber, and the desoak chamber with the main body.

37. A method for stacking devices in a semiconductor test apparatus comprising;
predesignating at least one user tray feeder for stacking un-tested devices;
predesignating at least one user tray sender for stacking tested devices;
designating at least one user tray feeder for stacking tested devices based on the test;
stacking at least one tested device on the at least one user tray feeder.

38. A method for testing a device using a semiconductor device test apparatus comprising:
providing a test chamber with a desired test space;
installing at least one test head on one side of the test chamber;
arranging a socket block and a plurality of socket guides to form a socket assembly, the socket block being positioned on the test head at a desired interval in a matrix form and having a plurality of sockets contacted with a plurality of devices, the socket guide covering an upper part of the socket block and having a plurality of socket guides provided with a plurality of windows to pass through a contact pin of the socket;
loading a plurality of inserts using a test tray;
arranging the inserts in a matrix to correspond to the arrangement of the socket, the inserts having a plurality of device receivers to receive devices corresponding to the plurality of sockets; and
assembling a lead pusher assembly to include a match plate, a plurality of pressure plates and a plurality of pushers, the match plate being arranged in parallel with the test head and being connected to a driving unit, the pressure plates being arranged in the match plate through a contact block in a matrix corresponding to the insert arrangement, the pushers being arranged in a side of the pressure plate and pressing a lead of the device.

39. A method for testing a semiconductor device including:
contacting a conductor that extends away from a perforated heat sink with the device during the testing cycle to dissipate heat from the device; and
flowing air through the perforations of the heat sink to make contact with the heat sink, the conductor, and the device to help control the temperature of the device during the testing cycle.

40. A method for controling a robot speed of a semiconductor device test apparatus, comprising the steps of:
sending control signals to at least one robot to carry a device for a test detecting a time for the test;
calculating a desired speed value of the robot corresponding to the test time detected; and
informing the corresponding robot of the calculated speed value to control the speed of the robot.

41. The method according to claim 40, wherein the time for the test begins when the device contacts a test head and ends when the device is released from the socket.

42. The method according to claim 40, wherein the step of detecting the time for the test includes retreiving stored values of pretested, like kind devices.
